(19) United States
(12) Patent Application Publication
(10) Pub. No.: US 2013/0168729 A1
(43) Pub. Date: Jul. 4, 2013

(54) Voltage-Sustaining Layer Consisting of Semiconductor and Insulator Containing Conductive Particles for Semiconductor Device

(71) Applicant: University of Electronic Science and Technology, Chengdu City (CN)

(72) Inventor: Xingbi Chen, Chengdu City (CN)

(73) Assignee: University of Electronic Science and Technology, Chengdu City (CN)

(21) Appl. No.: 13/689,146

(22) Filed: Nov. 29, 2012

(30) Foreign Application Priority Data
Nov. 30, 2011 (CN) 201110387593.8

(51) Int. Cl. H01L 29/06

(52) U.S. Cl. CPC H01L 29/0615
USPC 257/139; 257/487; 257/471; 257/565; 257/409; 257/168

(57) ABSTRACT

A semiconductor device has at least a cell between two opposite main surfaces. Each cell has a first device feature region contacted with the first main surface and a second device feature region contacted with the second main surface. There is a voltage-sustaining region between the first device feature region and the second device feature region, which includes at least a semiconductor region and an insulator region containing conductive particles. The semiconductor region and the insulator region contact directly with each other. The structure of such voltage-sustaining region can not only be used to implement high-voltage devices, but further be used as a junction edge technique of high-voltage devices.

### CROSS-REFERENCE TO RELATED APPLICATIONS

This application claims priority to Chinese Patent Application No. 201110387593.8, filed on Nov. 30, 2011 and entitled “Voltage-Sustaining Layer Consisting of Semiconductor and Insulator Containing Conductive Particles for Semiconductor Device”, which is incorporated herein by reference in its entirety.

### BACKGROUND OF THE INVENTION

1. Field of the Invention

The present invention relates to semiconductor devices, more specifically to the voltage-sustaining layer of semiconductor high-voltage and/or power devices.

2. Description of the Related Art

In the prior work (Ref. [1] Chinese patent ZL01139957.0 or U.S. Pat. No. 7,230,310B2), the present inventor proposed a structure of compound voltage-sustaining layer constructed by semiconductor and high permittivity dielectric for semiconductor devices. Such structure enables the voltage-sustaining layer to be heavily doped without arousing high electric field, which has a similar principle as the structure of super junction devices.

However, it is hard to find an appropriate material, which not only has the same coefficient of thermal expansion with the semiconductor to match with the high temperature of the power devices during its operation, but also has a high permittivity. Besides, high permittivity materials normally have ferro-electricity characteristics, whose permittivity relates to the history of the applied electric field. Obviously, it is detrimental to utilize ferroelectric material as high permittivity dielectric to implement such compound voltage-sustaining layer for the high-speed power devices.

### SUMMARY OF THE INVENTION

Inventors of this invention have found the above problems in the prior art, and provide a novel technical solution to address at least one of the problems.

The present invention can be summarized by referring the preferred embodiments described as follows.

1. According to a first aspect of this invention, a semiconductor device is provided, comprising a first main surface (the top surface except the electrode(s) in each figure) and a second main surface (the bottom surface except the electrode(s) in each figure), wherein at least a cell is located inbetween the first main surface and the second main surface, wherein the cell has a first device feature region (p⁺-region 24 in FIG. 2 and FIG. 3, M region 21 in FIG. 7, p-region 22 and M region 21 in FIG. 8, p-region 57 and n⁺-region 56 in FIG. 9, or p⁺-region 29, n⁺-region 30 and gate insulator region 32 in FIGS. 10-13) contacted with the first main surface and a second device feature region (n⁺-region 25 in FIG. 2, FIG. 3 and FIG. 7, n-region 20 and n⁺-region 25 in FIG. 8, n⁺-region 28 and n-region 45 in FIG. 10, n⁺-region 28 in FIG. 11, p⁺-region 36 in FIG. 12, p⁺-region 36 and n-region 46 in FIG. 13, p⁺-region 54 and n-region 55 in FIG. 14 or n⁺-region 51 in FIG. 16) contacted with the second main surface; a voltage-sustaining region (n-region 27 and I-region 38 in FIG. 2A, FIG. 3, FIG. 7, FIG. 8, FIG. 9, FIG. 14 and FIG. 16, p-region 37 and I-region 38 in FIG. 2B, n-region 27, p-region 37 and I-region 38 in FIG. 2C, FIG. 2D, FIGS. 11-13, n-region 43 and I-region 38 in FIG. 10) is located inbetween the first device feature region and the second device feature region, wherein:

the voltage-sustaining region includes at least a semiconductor region (n-region 27 in FIG. 2A, FIG. 3, FIG. 7, FIG. 8, FIG. 9, FIG. 14 and FIG. 16, p-region 37 in FIG. 2B, n-region 27 and p-region 37 in FIG. 2C, FIG. 2D, FIGS. 11-13, n-region 43 in FIG. 10) and an insulator region (I-region 38 in each figure) containing conductive particles;

the semiconductor region and the insulator region contact directly each other;

the semiconductor device comprising at least two electrodes, wherein:

one electrode is contacted directly with a portion or the total of the first main surface; another electrode is contacted directly with a portion or the total of the second main surface; these two electrodes are located outside of the region between the first main surface and the second main surface.

2. In the semiconductor device described in 1, the conductive particles in the insulator region of the voltage-sustaining region is distributed uniformly or not uniformly; the insulator containing conductive particles is a material with only one single chemical component or a material having mixed multiple different chemical components.

3. Referring to FIG. 4 and FIG. 5, a semiconductor device according to 1 comprises a plurality of close-packed cells, wherein in a cross section between the first device feature region and the second device feature region, structure of the voltage-sustaining region is interdigitated pattern (FIG. 4A, FIG. 5A), or hexagonal pattern (FIG. 4G, FIG. 4H, FIG. 5G, FIG. 5H), or rectangular pattern (FIG. 4D, FIG. 4E, FIG. 5D, FIG. 5E), or square pattern (FIG. 4B, FIG. 4C, FIG. 5B, FIG. 5C), or mosaic square pattern (FIG. 4F, FIG. 5F);

wherein in cross section with different distance to the first device feature region, the ratio of cross sectional area of the insulator containing conductive particles to cross sectional area of the semiconductor keeps constant (e.g., FIG. 2 and FIG. 3) or varies with the distance (e.g., FIG. 15 and FIG. 16).

4. Referring to FIG. 2 and FIG. 3, in the semiconductor device according to 1, the semiconductor region in a cell of the voltage-sustaining region includes a semiconductor region of the first conductivity type and/or a semiconductor region of the second conductivity type (e.g., the semiconductor region of the voltage-sustaining region in FIG. 2A is n-region 27, the semiconductor region of the voltage-sustaining region in FIG. 2B is p-region 37 and the semiconductor region of the voltage-sustaining region in FIG. 2C is constructed by n-region 27 and p-region 37).

5. Referring to FIG. 2, FIG. 3 and FIGS. 9-11, in the semiconductor device according to 1, the second device feature region is a semiconductor region of the first conductivity type (e.g., n⁺-region 25 in FIG. 2 and FIG. 3);

the first device feature region includes a semiconductor region of the second conductivity type (e.g., p⁺-region 24 in FIG. 2, FIG. 3 and p⁺-region 29 in FIG. 10) contacted directly with the semiconductor region of the voltage-sustaining region;

the first device feature region further includes a semiconductor region of the second conductivity type ((e.g., p⁺-region 24 in FIG. 2, FIG. 3 and p-region 57 in FIG. 9)) or a conductor (conductor for electrode S in FIG. 10 and FIG. 11) being contacted directly with the insulator region (I-region 38 in FIG. 2, FIG. 3 and FIGS. 9-11) containing conductive particles of the voltage-sustaining region.

6. Referring FIG. 13, in a semiconductor device according to 1, the second device feature region has a semiconductor region of the second conductivity type (p⁺-region 36) being contacted directly with the second main surface and a semiconductor region of the first conductivity type (n-region 46) being contacted directly with the semiconductor region of the second conductivity type; the semiconductor region of the first conductivity type (n-region 46) is also contacted with the voltage-sustaining region (n-region 27, p-region 37 and I-region 38);

the first device feature region (gate insulator region 32, p⁺-region 29 and n⁺-region 30) includes a semiconductor region of the second conductivity type (p⁺-region 29) contacted directly with the semiconductor region of the first conductivity type (n-region 27) of the voltage-sustaining region;

the first device feature region further includes a semiconductor region of the second conductivity type or a conductor (region 23) being contacted directly with the insulator region (I-region 38) containing conductive particles of the voltage-sustaining region.

Several kinds of devices are described as illustrative embodiments of the present invention:

7. Referring to FIG. 7, a semiconductor device according to 1 is a Schottky diode with metal-semiconductor contact, wherein the second device feature region is a semiconductor region of the first conductivity type (n⁺-region 25);

the first device feature region has a metal (M region 21) being contacted directly with semiconductor region of the first conductivity type (n-region 27) of the voltage-sustaining region (I-region 38 and n-region 27);

the first device feature region and the second device feature region are contacted with two conductors respectively serving as two electrodes (electrodes A and K, respectively) of the Schottky diode;

the first device feature region further has a semiconductor region of the second conductivity type or a conductor being contacted (M region 27) directly with the insulator region (I-region 38) containing conductive particles of the voltage-sustaining region.

8. Referring to FIG. 8, a semiconductor device according to 1 is a Junction Barrier Controlled Schottky (JBS) rectifier or a Merged P-i-N/Schottky (MPS) rectifier, wherein the second device feature region is a semiconductor region of the first conductivity type (n⁺-region 25 and n-region 20);

the first device feature region includes a metal region (M region 21) being contacted directly with semiconductor region of the first conductivity type (n-region 27) of the voltage-sustaining region (n-region 27 and I-region 38);

the first device feature region further includes a semiconductor region of the second conductivity type (p-region 22) being contacted directly with semiconductor region of the first conductivity type (n-region 27) of the voltage-sustaining region and the metal region;

the first device feature region and the second device feature region are contacted with two conductors respectively serving as two electrodes (anode A and cathode K) of the JBS rectifier or the MPS rectifier.

9. Referring to FIG. 9, a semiconductor device according to 5 is a Bipolar Junction Transistor (BJT), wherein the second device feature region is the semiconductor region of the first conductivity type (n⁺-region 58);

the voltage-sustaining region has at least a semiconductor region of the first conductivity type (n-region 27) serving as a collector region of the BJT;

the semiconductor region of the second conductivity type (p-region 57) of the first device feature region serves as a base region of the BJT;

the first device feature region further includes a semiconductor region of the first conductivity type (n⁺-region 56) surrounded by the base region except the part on the first main surface, serving as an emitter region of the BJT;

a conductor covering on the semiconductor region of the first conductivity type (n⁺-region 58) of the second device feature region serves as a collector electrode (electrode C), a conductor covering on the base region (p-region 57) serves as a base electrode (electrode B) and a conductor covering on the emitter region (n⁺-region 56) serves as an emitter electrode (electrode E).

10. Referring to FIG. 10 and FIG. 11, a semiconductor device according to 5 is a Metal-Insulator-Semiconductor Field Effect Transistor (MISFET), wherein the second device feature region is a semiconductor region of the first conductivity type (n⁺-region 28), serving as drain region of the MISFET;

the voltage-sustaining region has at least a semiconductor region of the first conductivity type (n-region 43 in FIG. 10 and n-region 27 in FIG. 11) serving as a drift region of the MISFET;

the semiconductor region of the second conductivity type (p⁺-region 29) of the first device feature region serves as a source-body region of the MISFET;

the first device feature region further includes a semiconductor region of the first conductivity type (n⁺-region 30) surrounded by the source-body region (p⁺-region 29) except the part on the first main surface, serving as a source region of the MISFET;

an insulator layer (region 32) covers on the first main surface started from a part of the source region, through an area of the source-body region, ended at a part of the semiconductor region of the first conductivity type of the voltage-sustaining region, serving as a gate insulator of the MISFET;

a conductor covering on the drain region (n⁺-region 28) serves as a drain electrode (electrode D), a conductor contacted with the source-body region (p⁺-region 29) and the source (n⁺-region 30) region serves as a source electrode (electrode S) and a conductor covering on the gate insulator (region 32) serves as a gate electrode (electrode G).

11. Referring to FIG. 12 and FIG. 13, a semiconductor device according to 6 is an Insulator Gate Bipolar Transistor (IGBT), wherein the semiconductor region of the second conductivity type (p⁺-region 36) of the second device feature region is an anode region of the IGBT;

the semiconductor region of the second conductivity type (p⁺-region 29) of the first device feature region serves as a source-body region of MISFET in the IGBT;

the first device feature region further includes a semiconductor region of the first conductivity type (n⁺-region 30) surrounded by the source-body region (p⁺-region 29) except the part on the first main surface, serving as a source region of the MISFET in the IGBT;

an insulator layer (region 32) covers on the first main surface started from a part of the source region, through an area of the source-body region, ended at a part of the semiconductor region of the first conductivity type of the voltage-sustaining region, serving as a gate insulator of the MISFET in the IGBT;

a conductor covering on the anode region serves as an anode electrode (electrode A), a conductor contacted with the source-body region and the source region serves as a cathode electrode (electrode K) and a conductor covering on the gate insulator serves as a gate electrode (electrode G).

12. Referring to FIG. 14, a semiconductor device according to 6 is a thyristor, wherein the semiconductor region of the second conductivity type (p⁺-region 54) in the second device feature region is an anode region of the thyristor;

the semiconductor region of the second conductivity type (p-region 53) of the first device feature region serves as a gate region of the thyristor;

the first device feature region further includes a semiconductor region of the first conductivity type (n-region 52) surrounded by the gate region except the part on the first main surface, serving as a cathode region of the thyristor;

a conductor covering on a part of the gate region and the insulator region containing conductive particles of the voltage-sustaining region serves as a gate electrode (electrode G) of the thyristor;

a conductor covering on the anode region (p⁺-region 54) serves as an anode electrode (electrode A) and a conductor covering on the cathode region serves as a cathode electrode (electrode K).

Obviously, the present invention can also be used for many other high-voltage devices, e.g. Light Controlled Thyristor (LCT), Gate Turn-Off Thyristor (GTO), MOS Controlled Thyristor (MCT), Junction Field Effect Transistor (JFET), Static-Induction Transistor (SIT), and so on.

It is noted that the present invention can also be used as a junction edge technique for many kinds of devices.

13. Referring to FIG. 16, in a semiconductor device according to 1, a cell of the device is located at an edge(s) (the edge of the structure shown in FIG. 2) of operation region of a semiconductor device, serving as a junction edge technique for sustaining voltage; the insulator (I-region 38) containing conductive particles of the voltage-sustaining region is contacted with a semiconductor region of the second conductivity type (p⁺-region 24 in FIG. 2) of the first device feature region through a semiconductor region of the second conductivity type (p-region 50 in FIG. 16A) or a conductor (electrode A in FIG. 16B).

### BRIEF DESCRIPTION OF THE DRAWINGS

The accompanying drawings, which are incorporated in and constitute a part of the specification, illustrate embodiments of the invention and, together with the description, serve to explain the principles of the invention.

With reference to those drawings, from the following detailed description, this invention can be understood more clearly, wherein:

FIG. 1 is a schematic diagram illustrating the conductive particles in the insulator inducing a pair of positive and negative charges under the electric field.

FIGS. 2A, 2B, 2C, and 2D, collectively referred to as FIG. 2 show the schematic diagrams of the voltage-sustaining region constructed by semiconductor and insulator containing conductive particles;

FIG. 2A schematically shows the voltage-sustaining region constructed by insulator containing conductive particles and n-type semiconductor;

FIG. 2B schematically shows the voltage-sustaining region constructed by insulator containing conductive particles and p-type semiconductor region;

FIG. 2C schematically shows the voltage-sustaining region constructed by n-type semiconductor region, p-type semiconductor region and insulator containing conductive particles, wherein the insulator is located between p-type semiconductor regions;

FIG. 2D schematically shows the voltage-sustaining region constructed by n-type semiconductor region, p-type semiconductor region and insulator containing conductive particles, wherein the insulator is located between p-type semiconductor region and n-type semiconductor region;

FIGS. 3A, 3B, 3C, and 3D, collectively referred to as FIG. 3 show the schematic diagrams comparing the widths and thicknesses of semiconductor and insulator containing conductive particles of voltage-sustaining region.

FIG. 3A is a schematic diagram that the widths of insulator containing conductive particles and n-type semiconductor region are not necessary equal.

FIG. 3B is a schematic diagram that the thickness of n-type semiconductor region is larger than that of insulator containing conductive particles, and the insulator does not reach the n⁺-region 25 of the second device feature region.

FIG. 3C is a schematic diagram that the thickness of insulator containing conductive particles is larger than that of n-type semiconductor region, wherein the bottom of insulator, lower than that of n-region 27, has extended into the n⁺-region 25 of second device feature region.

FIG. 3D is another schematic diagram that the thickness of insulator containing conductive particles is larger than that of n-type semiconductor region, wherein the top of insulator is higher than that of n-region 27.

FIGS. 4A, 4B, 4C, 4D, 4E, 4F, 4G, and 4H, collectively referred to as FIG. 4 schematically show top-views of different arrangement for the insulators containing conductive particles and semiconductor regions at the cross-section II-IF in FIG. 2A. Cells are demarked by dashed lines (except FIG. 4A with dashed-dotted lines) between them:

FIG. 4A schematically shows an interdigitated pattern;

FIG. 4B schematically shows a pattern formed by square cells, wherein semiconductor regions are all mutually connected;

FIG. 4C schematically shows a pattern formed by square cells, wherein insulator regions containing conductive particles are mutually connected;

FIG. 4D schematically shows a pattern formed by rectangular cells, wherein semiconductor regions are all mutually connected;

FIG. 4E schematically shows a pattern formed by rectangular cells wherein insulator regions containing conductive particles are mutually connected;

FIG. 4F schematically shows a mosaic square pattern;

FIG. 4G schematically shows a hexagonal close-packed pattern, wherein semiconductor regions are all mutually connected;

FIG. 4H schematically shows a hexagonal close-packed pattern, wherein insulator regions containing conductive particles are all mutually connected.

FIGS. 5A, 5B, 5C, 5D, 5E, 5F, 5G, 5H, and 5I, collectively referred to as FIG. 5 schematically show top-views of different arrangements for n-type semiconductor regions, p-type semiconductor regions and the insulators containing conductive particles at the cross-section III-III′ in FIG. 2D:

FIG. 5A schematically shows an interdigitated pattern;

FIG. 5B schematically shows a pattern formed by square cells, wherein n-type semiconductor regions are all mutually connected;

FIG. 5C schematically shows a pattern formed by square cells, wherein p-type semiconductor regions are all mutually connected;

FIG. 5D schematically shows a pattern formed by rectangular cells, wherein n-type semiconductor regions are all mutually connected;

FIG. 5E schematically shows a pattern formed by rectangular cells, wherein p-type semiconductor regions are all mutually connected;

FIG. 5F schematically shows a mosaic square pattern;

FIG. 5G schematically shows another mosaic square pattern;

FIG. 5H schematically shows a hexagonal close-packed pattern, wherein n-type semiconductor regions are all mutually connected;

FIG. 5I schematically shows a hexagonal close-packed pattern, wherein p-type semiconductor regions are all mutually connected.

FIG. 6 schematically shows the structure of voltage-sustaining region constructed by semiconductor and insulator containing conductive particles, wherein there is a thin silicon dioxide layer between semiconductor and insulator containing conductive particles.

FIG. 7 schematically shows a structure of Schottky diode using the voltage-sustaining layer constructed by semiconductor and insulator containing conductive particles.

FIGS. 8A and 8B, collectively referred to as FIG. 8 schematically show the structures of Schottky rectifier using the voltage-sustaining layer constructed by semiconductor and insulator containing conductive particles:

FIG. 8A schematically shows a structure of high-voltage Merged P-i-N/Schottky using the voltage-sustaining layer constructed by semiconductor and insulator containing conductive particles;

FIG. 8B schematically shows another structure of high-voltage Junction Barrier Controlled Schottky using the voltage-sustaining layer constructed by semiconductor and insulator containing conductive particles.

FIG. 9 schematically shows a structure of high-voltage Bipolar Junction Transistor using the voltage-sustaining layer constructed by semiconductor and insulator containing conductive particles.

FIG. 10 schematically shows a structure of high-voltage n-VDMIST using the voltage-sustaining layer constructed by semiconductor and insulator containing conductive particles, wherein the insulators containing conductive particles is contacted indirectly to the n⁺ drain region through a lightly doped n-region.

FIG. 11 schematically shows a method to implement n-VDMIST by using the structure shown in FIG. 5D as the voltage-sustaining region.

FIG. 12 schematically shows a method to implement IGBT by using the structure shown in FIG. 5D as the voltage-sustaining region.

FIG. 13 schematically shows a method to implement IGBT with a buffer layer by using the structure shown in FIG. 5D as the voltage-sustaining region.

FIG. 14 schematically shows a structure of thyristor using the voltage-sustaining layer constructed by semiconductor and insulator containing conductive particles.

FIGS. 15A, 15B, 15C, and 15D, collectively referred to as FIG. 15 schematically illustrate one fabrication process to manufacture a VDMIS with voltage-sustaining region constructed by semiconductor and insulator containing conductive particles:

FIG. 15A schematically illustrates that an epitaxial layer n-region is grown on n⁺-substrate;

FIG. 15B schematically illustrates that a groove with a depth close to the thickness of epitaxial layer is etched in the epitaxial layer;

FIG. 15C schematically illustrates that the grooves are filled with the insulator containing conductive particles;

FIG. 15D schematically illustrates that the electrodes are formed;

FIGS. 16A, 16B, and 16C, collectively referred to as FIG. 16 schematically show junction edge structures constructed of semiconductor and insulator containing conductive particles:

FIG. 16A schematically shows an application of using the insulator containing conductive particles to implement the terminal cell of a p-n junction diode;

FIG. 16B schematically shows another application of using the insulator containing conductive particles to implement the terminal cell of a p-n junction diode, wherein the insulator is contacted directly with anode electrode A at the first main surface;

FIG. 16C schematically shows still another application of using the insulator containing conductive particles as junction edge technique, wherein the insulator containing conductive particles is not necessary to be covered by conductor but it covers on a considerable part of p-region.

### DESCRIPTION OF THE PREFERRED EMBODIMENTS

Various exemplary embodiments of the present invention will now be described in detail with reference to the drawings. It should be noted that the relative arrangement of the components and steps, the numerical expressions, and numerical values set forth in these embodiments do not limit the scope of the present invention unless it is specifically stated otherwise.

Meanwhile, it should be appreciated that, for the convenience of description, various parts shown in those drawings are not necessarily drawn on scale.

The following description of at least one exemplary embodiment is merely illustrative in nature and is in no way intended to limit the invention, its application, or uses.

Techniques, methods and apparatus as known by one of ordinary skill in the relevant art may not be discussed in detail but are intended to be part of the specification where appropriate.

In all of the examples illustrated and discussed herein, any specific values should be interpreted to be illustrative only and non-limiting. Thus, other examples of the exemplary embodiments could have different values.

Notice that similar reference numerals and letters refer to similar items in the following figures, and thus once an item is defined in one figure, it is possible that it need not be further discussed for following figures.

In the present invention, a new method by using a normal insulator, which contains a large number of conductive particles to replace the high permittivity dielectric in Ref [1] mentioned above, is proposed. Macroscopically, the insulator containing conductive particles has the same property with the high permittivity dielectric material demanded by Ref. [1]. For better understanding, the principle of the difference between the permittivity of material and that of vacuum is explained firstly. Now, in a certain material under the electric field with a frequency far lower than that of the visible light, the electric field can cause the movement between the electrons and atomic nucleus in atom, or the movement between the negative and positive ions in ionic crystal, or the directional movement of electric dipole in material with polar molecules. These movements arouse the polarization along the direction of electric field. And the electric displacement, or electric flux density, D, is increased by the electric polarization, or the total dipole moment per unit volume, P, which is proportional to the electric field strength E. Thus, D=∈₀E⁺P=∈_{I}E, where ∈₀ stands for the permittivity of vacuum and ∈_{I} stands for the permittivity of material. So, it is evident that ∈_{I}>∈₀.

Since the insulator containing the conductive particles can be solid, colloid, plastic, liquid or even the mixture of them, therefore, the problems of ferro-electricity and the inconsistence of expansion coefficient mentioned above can be avoided.

It should be mentioned here that the conductive particles contained in the insulator region for using in the voltage-sustaining region proposed in the present invention are not necessary to be distributed very evenly.

It should also be mentioned here that the insulator used in the present invention for voltage-sustaining region is not limited to a material with only one single chemical component inside of it.

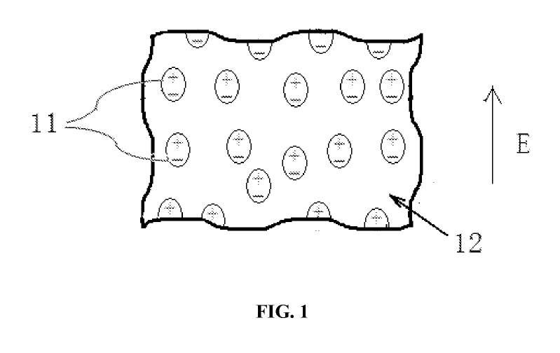

As can be seen from FIG. 1, the conductive particles 11 in the insulator 12 are polarized by electric field. When the direction of electric field is from bottom to top along the paper, a negative charge is induced on the bottom surface of each particle, marked as “−” in this figure, and a positive charge is induced on the top surface of each particle, marked as “+”. Since the quantity of induced negative charge and positive charge is equal, the total charge of particle maintains the same. But the particle itself causes a dipole moment, which produces electric fluxes to outside of the particle. If there are a large number of such dipole moments, an average electric flux exists as an overall effect with a direction from bottom to top, thus producing a value of P. That is to say, macroscopically, the conductive particles in the insulator can increase its effective permittivity.

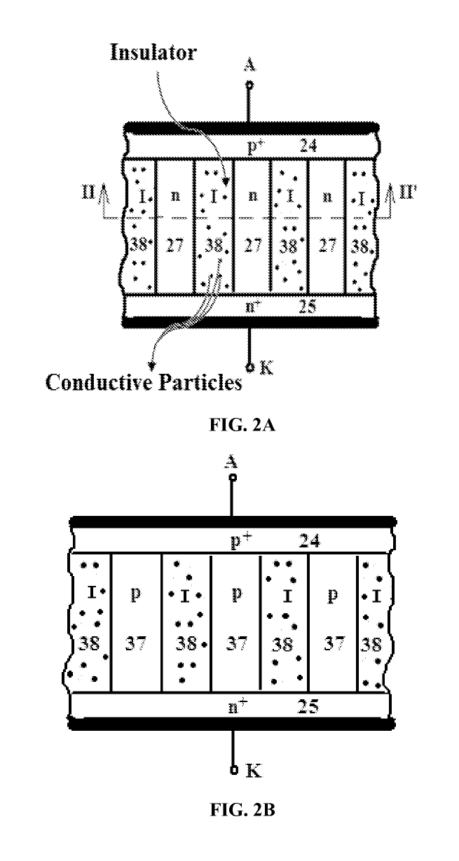

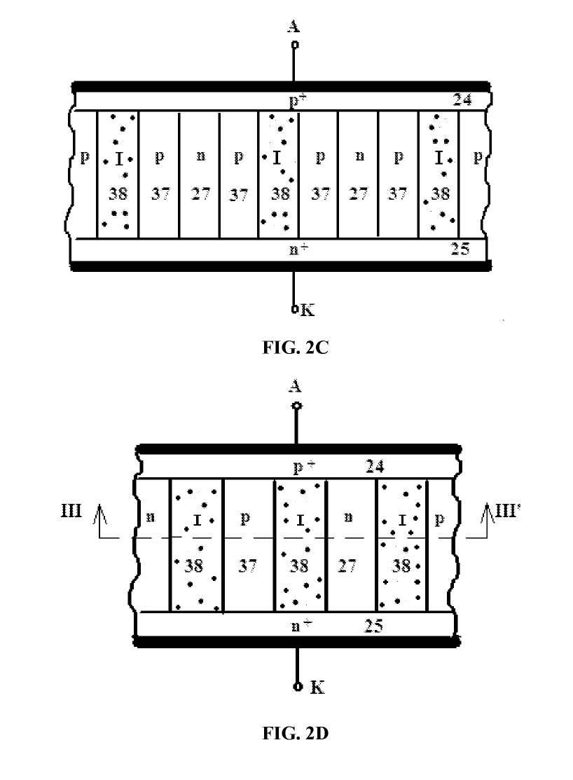

The technology schemes of the present invention will be described and illustrated in detail with reference to the drawings, wherein the illustrative embodiments of the present invention will be demonstrated in the following. In all of the figures, the same number means the same component or element. The solid bold lines represent the conductor for electrode contacts, S stands for the semiconductor regions and I stands for the insulator containing the conductive particles. In present invention, regions I can be used to replace the high permittivity region described in Ref [1]. There is a first device feature region and a second device feature region respectively contacted with the opposite sides of the voltage-sustaining region implemented by using this method. FIG. 2A schematically shows a diode by using n-type semiconductor regions 27 and insulators 38 containing conductive particles to serve as voltage-sustaining region, wherein p⁺-region 24 is the first device feature region which is contacted with anode electrode A and n⁺-region 25 is the second device feature region which is contacted with cathode electrode K. The black spots in the insulators stand for the conductive particles. Obviously, the n-type semiconductor regions in FIG. 2A can be replaced by p-type regions, as shown in FIG. 2B. In FIG. 2C, the voltage-sustaining region is constructed by the insulators 38 containing conductive particles, n-type semiconductor regions 27 and p-type semiconductor regions 37, wherein the insulators 38 are between two p-type semiconductor regions 37. In the voltage-sustaining region shown in FIG. 2D, each insulator is located between an n-type semiconductor region 27 and a p-type semiconductor region 37.

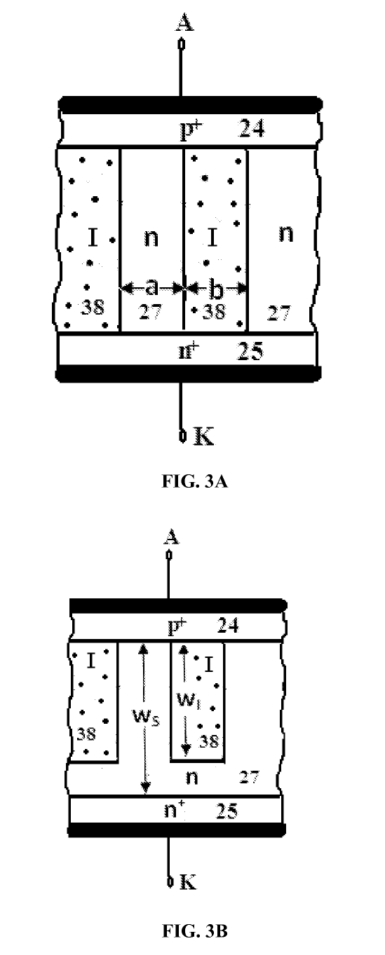

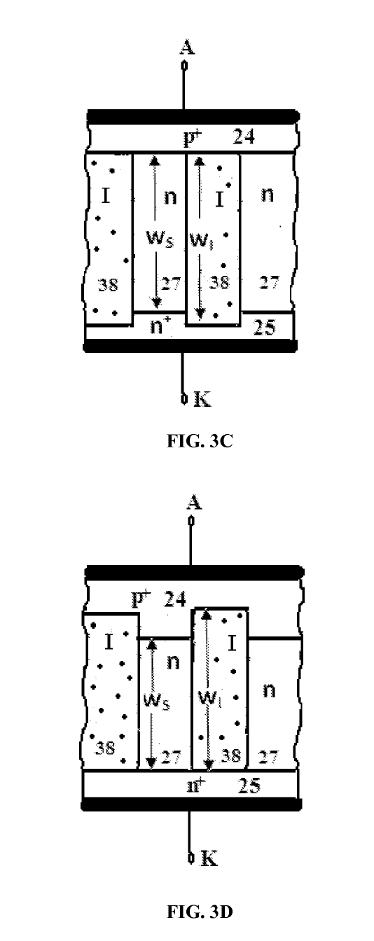

It should be noted that in the voltage-sustaining region, it is not necessary for the insulators containing conductive particles to have the same width and thickness with semiconductor regions. In FIG. 3A, marks a and b stand for the widths of n-region 27 and I-region 38 shown in FIG. 2A, respectively. a is not required to equal to b. In the voltage-sustaining region shown in FIG. 3B, the thickness W_{I} of insulator 38 containing conductive particles is smaller than the width W_{S} of n-type semiconductor region 27. In FIG. 3C, the thickness W_{I} of insulator 38 containing conductive particles is larger than the thickness W_{S} of n-type semiconductor region 27 and I-regions have extended into the second device feature region 25. In FIG. 3D, the thickness W_{I} of insulator 38 containing conductive particles is also larger than the width Ws of n-type semiconductor region 27 and the interfaces between the first device feature region 24 and them are not in the same plane.

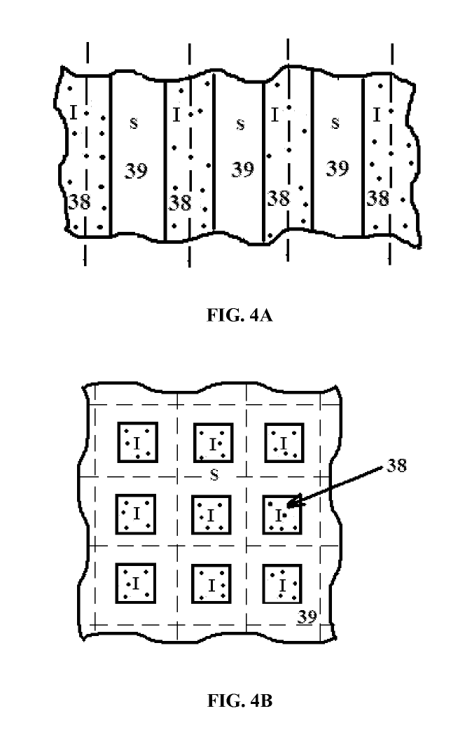

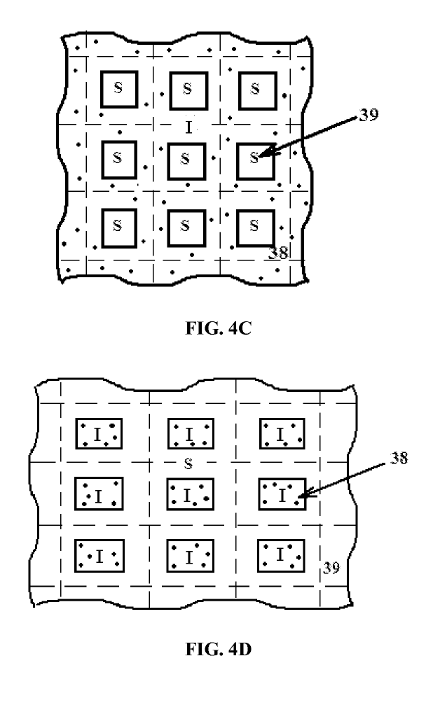

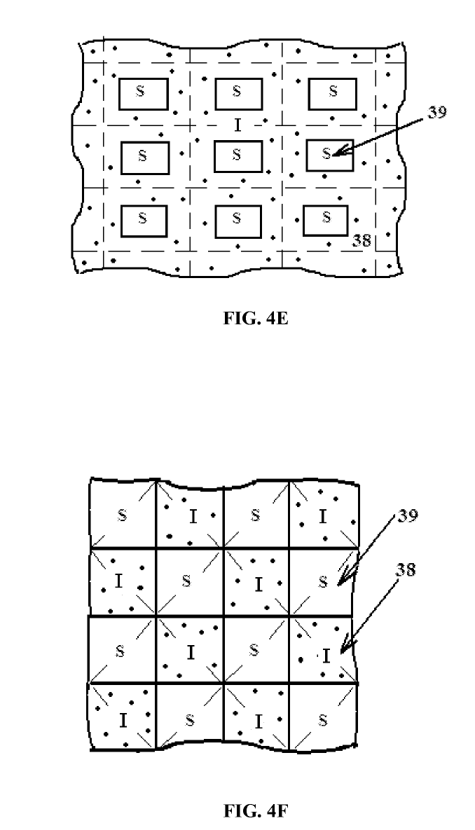

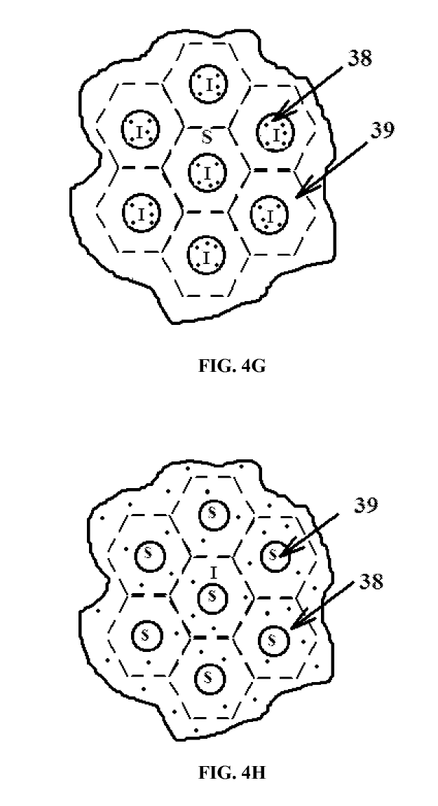

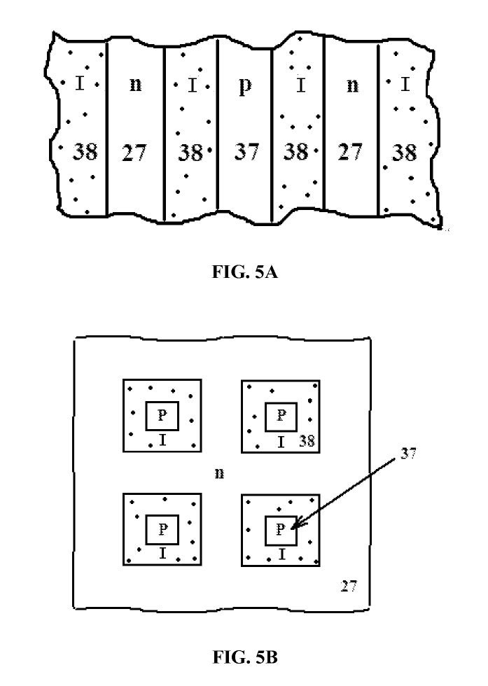

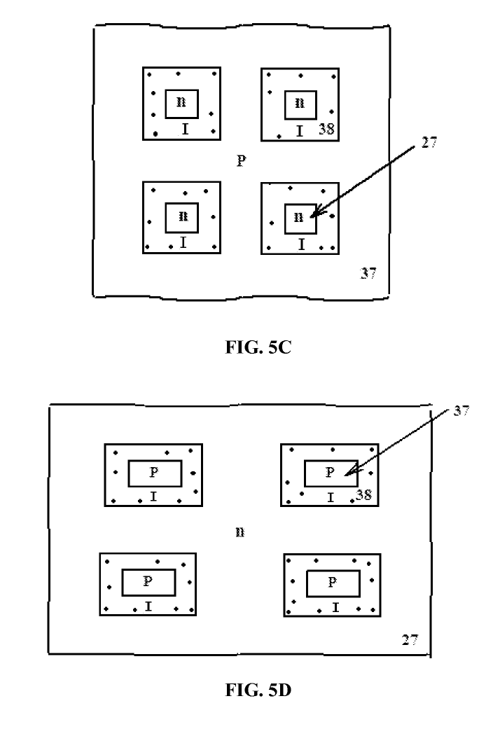

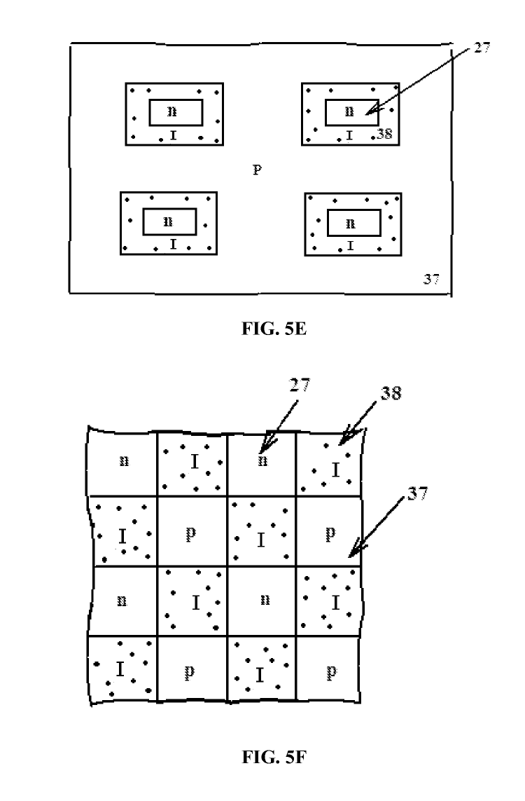

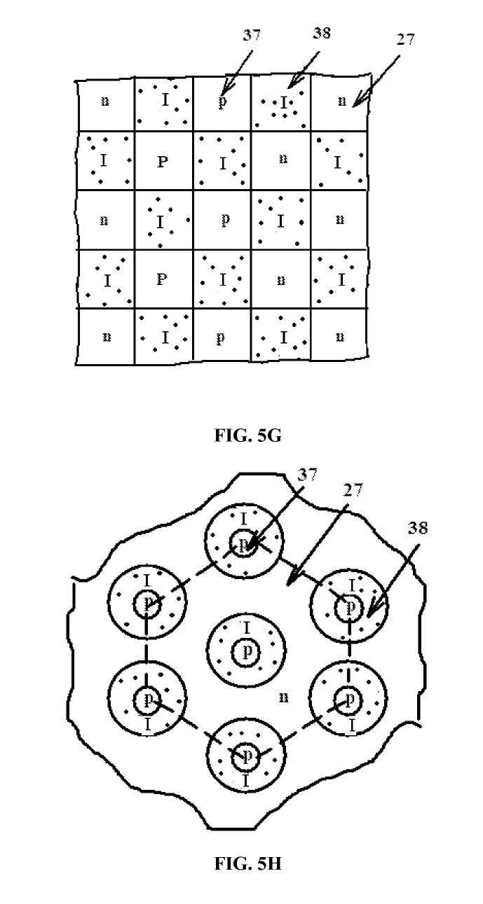

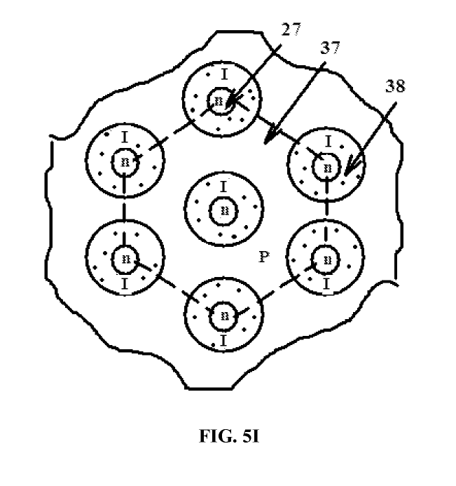

There are many structure patterns for the arrangement of the insulators containing conductive particles and semiconductor regions. FIG. 4 shows some arrangements for the insulators 38 containing conductive particles and semiconductor regions 39 as viewed along II-II′ section in FIG. 2A. Cells are demarked by dashed lines (except FIG. 4A with dashed-dotted lines) between them in the figure. These patterns include interdigitated pattern as shown in FIG. 4A; a pattern formed by square cells, wherein semiconductor regions are all mutually connected as shown in FIG. 4B; a pattern formed by square cells, wherein insulator regions containing conductive particles are mutually connected as shown in FIG. 4C; a pattern formed by rectangular cells, wherein semiconductor regions are all mutually connected as shown in FIG. 4D; a pattern formed by rectangular cells, wherein insulator regions containing conductive particles are mutually connected as shown FIG. 4E; a mosaic square pattern as shown in FIG. 4F; a hexagonal close-packed pattern, wherein semiconductor regions are all mutually connected as shown in FIG. 4G; a hexagonal close-packed pattern, wherein insulator regions containing conductive particles are all mutually connected as shown in FIG. 4H. FIG. 5 shows some arrangements for the insulators 38 containing conductive particles, n-type semiconductor regions 27 and p-type semiconductor regions 37 as viewed along III-III′ section in FIG. 2D. These patterns include interdigitated pattern as shown in FIG. 5A; a pattern formed by square cells, wherein n-type semiconductor regions 27 are all mutually connected as shown in FIG. 5B; a pattern formed by square cells, wherein p-type semiconductor regions 37 are all mutually connected as shown in FIG. 5C; a pattern formed by rectangular cells, wherein n-type semiconductor regions 27 are all mutually connected as shown in FIG. 5D; a pattern formed by rectangular cells, wherein p-type semiconductor regions 37 are all mutually connected as shown in FIG. 5E; a mosaic square pattern as shown in FIG. 5F; another mosaic square pattern as shown in FIG. 5G; a hexagonal close-packed pattern, wherein n-type semiconductor regions 27 are all mutually connected as shown in FIG. 5H; a hexagonal close-packed pattern, wherein p-type semiconductor regions 37 are all mutually connected as shown in FIG. 5I;

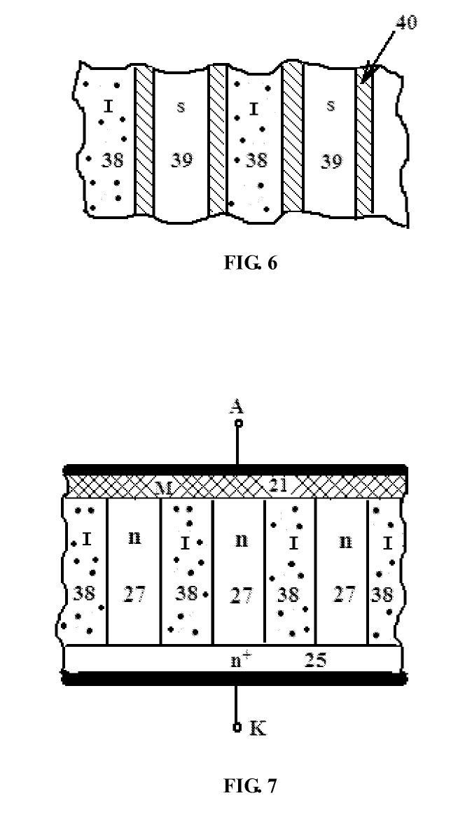

If the semiconductor mentioned above is silicon, it can be separated with the insulator containing conductive particles by a thin silicon dioxide layer 40 between them, as shown in FIG. 6. In this figure, the shaded area 40 stands for the silicon dioxide layer. Although the permittivity of silicon dioxide is very low, it will not prevent the electric fluxes of the semiconductor regions S from flowing to the insulators containing conductive particles, or the electric fluxes of the insulators containing conductive particles from flowing to the semiconductor regions S, as long as the silicon dioxide layer 40 is thin enough.

A Schottky diode can also be implemented by replacing the p⁺-region 24 in FIG. 2 with metal, as shown in FIG. 7. In this figure, metal M (27) is the first device feature region.

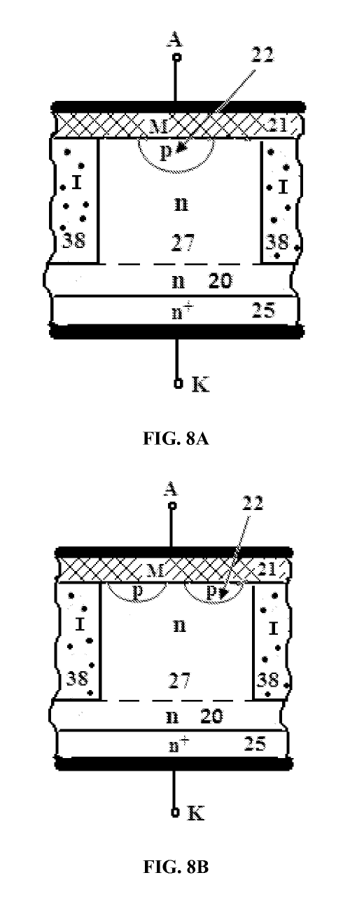

The present invention can also be used to implement high-voltage Junction Barrier Controlled Schottky (JBS) rectifier or pinch rectifier. Similarly, it can also be used to implement high-voltage Merged P-i-N/Schottky (MPS) rectifier. All of their structures can be schematically shown as FIG. 8.

The first device feature region of the devices shown in FIG. 8A and FIG. 8B includes a metal layer M and p-region 22 contacted directly with M. There is a connection of electrode A covering on the first device feature region. The second device feature region of the devices shown in these two figures includes n-region 20 and n⁺-region 25 contacted with the electrode K underneath it.

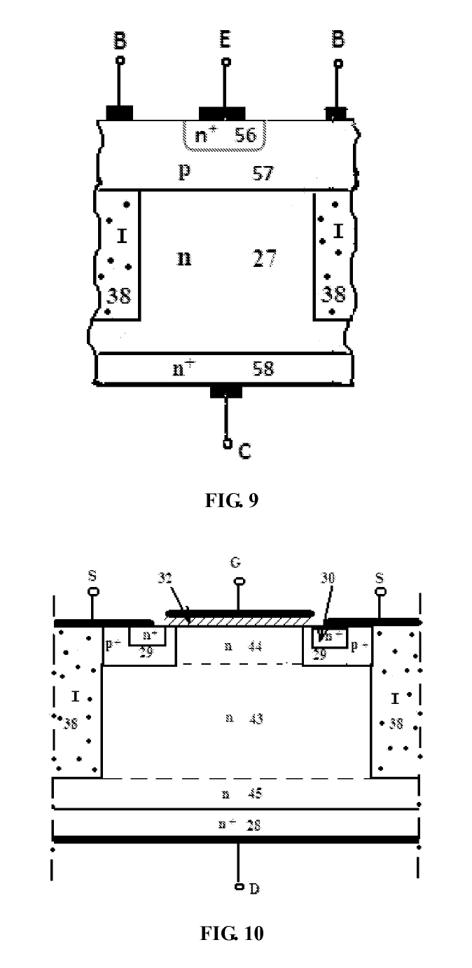

The present invention can also be used to implement high-voltage Bipolar Junction Transistor (BJT), as shown in FIG. 9. This figure shows an npn BJT. In the first device feature region of this device, there is a p-base region 57 with an n⁺-emitter region 56 in its upper central part. On the top of the first device feature region, there is an emitter electrode E contacted with n⁺-emitter region 56 and a base electrode B contacted with p-region 57. The second device feature region is n⁺-region 58 contacted with collector electrode C underneath it.

FIG. 10 schematically shows one method to implement an n-VDMIST by using the present invention. In this figure, p⁺-region 29 is the source-body region, n⁺-region 30 is source region and insulator layer 32 is gate insulator. The insulators 38 containing conductive particles are not contacted directly, but contacted indirectly through an n-region 45, which is heavier doped than n-region 43, to the n⁺ drain region 28. Due to the existence of this n-region 45, the resistance of the part close to n⁺ drain region 28 of the turn-on VDMIST is further diminished. Although when a reverse voltage is applied across drain electrode D and source electrode S, there is a little part of voltage drop across region 44 and region 45 in the figure, yet the voltage sustained by the device is dominantly drop across region 43. Therefore, the second device feature region includes n-region 45 and n⁺ drain region 28.

FIG. 11 schematically shows another method to implement an n-VDMIST by using the structure shown in FIG. 5D as the voltage-sustaining region. In this structure, the voltage-sustaining region also includes p-region 37.

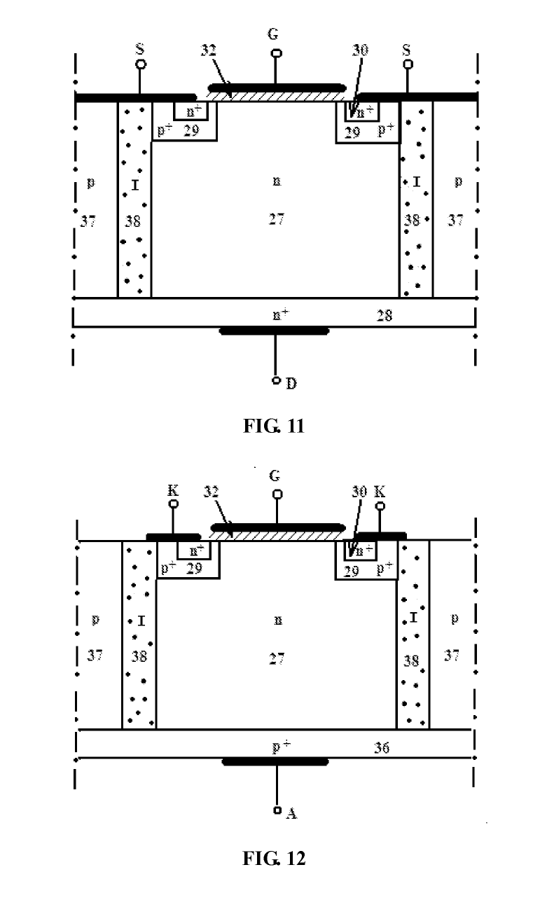

FIG. 12 schematically shows an IGBT by using the present invention. It is different from the VDMIST shown in FIG. 11 mainly in that the second device feature region is a p⁺-region 36 instead of the n⁺-region 28.

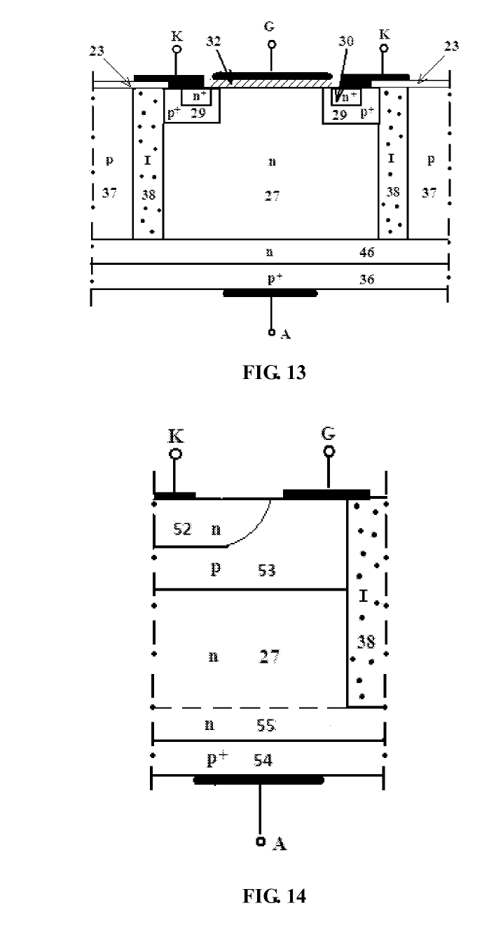

FIG. 13 schematically shows another IGBT with a buffer layer (region 46), which is implemented by using the present invention. It is different from FIG. 12 mainly in that, in the second device feature region, besides p⁺-region 36, there is an n-buffer layer 46 thereon. The region 23 in this figure can either be a p⁺-region or a conductor.

In the present invention, it is not necessary for the insulator containing conductive particles of the voltage-sustaining region to have the same depth with semiconductor. For example, in FIG. 10, the bottom of insulator 38 is shallower than n-region with a thickness of n-region 45. Of course, such insulator can also reach into the n⁺-region 28.

The technique in the present invention can also be used to implement the voltage-sustaining region of thyristor and a specific application is shown in FIG. 14. This figure shows a cell of pnpn layers. The first device feature region of this device includes p-region 53 and n-region 52 surrounded by it. Above the n-region 52, there is a cathode electrode K contacted with it. A gate electrode G covering on p-region 53 is also connected to the top of the insulator containing conductive particles through conductor. The second device feature region of the thyristor includes n-region 55 and p⁺-region 54. There is an anode electrode A contacted with the bottom of p⁺-region 54.

Obviously, the present invention can also be used for many other high-voltage devices, e.g. Light Controlled Thyristor (LCT), Gate Turn-Off Thyristor (GTO), MOS Controlled Thyristor (MCT), Junction Field Effect Transistor (JFET), Static-Induction Transistor (SIT), and so on.

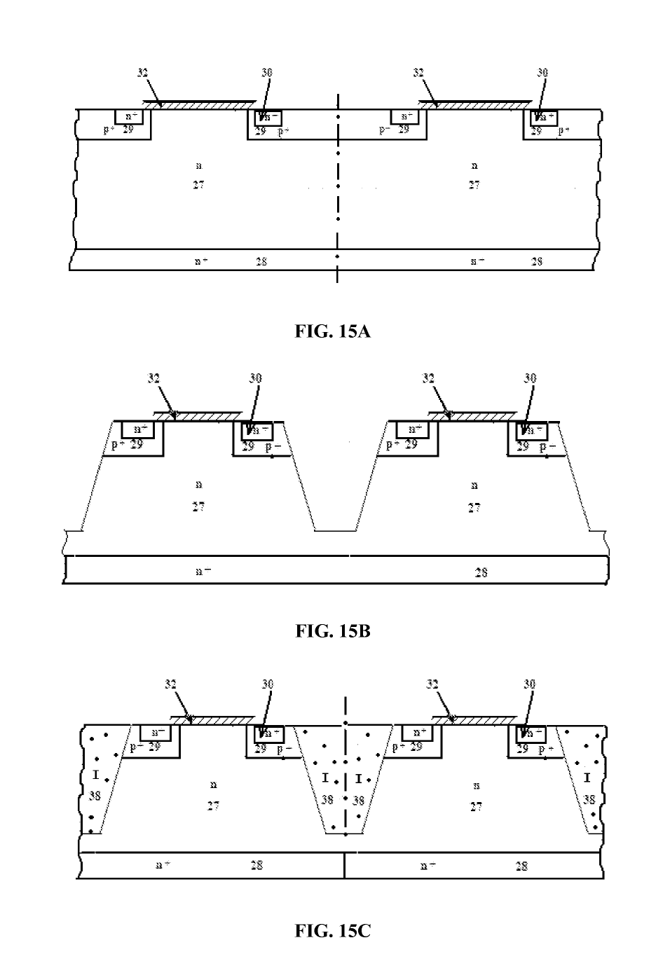

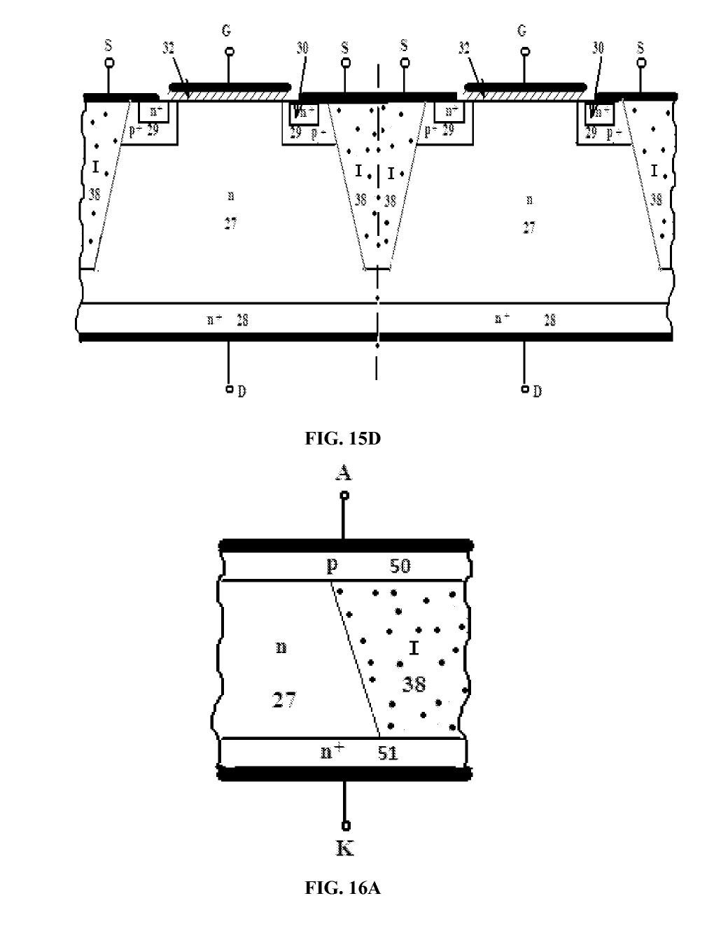

FIG. 15 shows the fabrication process to manufacture a VDMIST shown in FIG. 10. Firstly, an epitaxial layer n-region 27 is grown on n⁺-substrate 28. Then, p⁺ source-body region 29, n⁺ source region 30 and gate insulator 32 are formed by using the conventional method of manufacturing VDMIST. After masking the place without need to be grooved, a deep groove is etched by means of chemical-etching or plasma-etching, forming a cove between two n-regions 27 as shown in FIG. 15B. Next, place the wafer in a vacuum container. As soon as evacuate the container, fill the grooves with colloid containing conductive particles. Since the grooves are vacuumed, the colloid can be absorbed in it. Then conduct a planarization on the surface of the colloid containing conductive particles, as shown in FIG. 15C. Thereafter, the electrodes D, S and G are formed at the top and bottom, as shown in FIG. 15D.

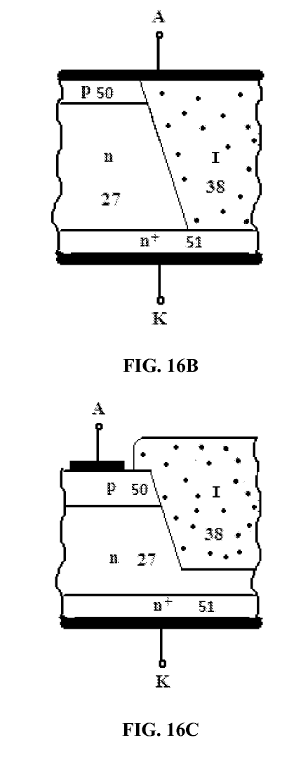

The present invention can not only be used for the operation region of various kinds of devices, but also can be used as a junction edge technique for many kinds of devices. FIG. 16A shows a specific application of using the insulator containing conductive particles to implement the terminal cell of a p-n junction diode. Herein, the left part is connected to the operation region of device, and as long as the right part containing conductive particles have a certain width and having a p-region which is the same with p-region 50 or a conductor contacted with p-region 50 on it, as shown in FIG. 16B, it can be used as the junction edge of the diode.

FIG. 16C shows another application of using the insulator containing conductive particles as the junction edge technique. Herein, the insulator 38 containing conductive particles is not necessary to be covered by conductor but it covers on a considerable part of p-region 50.

Obviously, all of the n-regions and p-regions in the above demonstration can be exchanged each other, the device then changes to a device of a conductivity of opposite type.

It should be understood that various other examples of application, which should be included in the scope of the present invention as defined in the claims, will be apparent to those skilled in the art.

Thus, the semiconductor device of this invention has been described in detail. Some well known details are not described herein in order to prevent obscuring the concept of this invention.

From the above description, those skilled in the art may fully understand how to implement the technical solutions disclosed herein.

Although some specific embodiments of the present invention have been demonstrated in detail with examples, it should be understood by a person skilled in the art that the above examples are only intended to be illustrative but not to limit the scope of the present invention. It should be understood by a person skilled in the art that the above embodiments can be modified without departing from the scope and spirit of the present invention. The scope of the present invention is defined by the attached claims.

### REFERENCES

[1] X. B. Chen, U.S. Pat. No. 7,230,310 B2, or Chinese patent ZL01139957.0.

What is claimed is:

1. A semiconductor device, comprising a first main surface and a second main surface opposite to said first main surface, wherein at least a cell is located inbetween said first main surface and said second main surface, wherein said cell has a first device feature region contacted with said first main surface and a second device feature region contacted with said second main surface; wherein a voltage-sustaining region is located inbetween said first device feature region and said second device feature region, wherein said voltage-sustaining region includes at least a semiconductor region and an insulator region containing conductive particles; wherein said semiconductor region and said insulator region contact directly each other;
said semiconductor device comprising at least two electrodes, wherein:
one electrode is contacted directly with a portion or the total of said first main surface, another electrode is contacted directly with a portion or the total of said second main surface, and said two electrodes are located outside of the region between said first main surface and said second main surface.

2. A semiconductor device according to claim 1, wherein said conductive particles in said insulator region of said voltage-sustaining region is distributed uniformly or not uniformly; and wherein in said insulator region containing conductive particles, said insulator is made of a material with only one single chemical component or a material having mixed multiple different chemical components.

3. A semiconductor device according to claim 1, comprising a plurality of close-packed cells, wherein in a cross section between said first device feature region and said second device feature region, the cross section structure of said voltage-sustaining region is interdigitated pattern, or hexagonal pattern, or rectangular pattern, or square pattern, or mosaic square pattern;
wherein the ratio of the cross sectional area of said insulator region containing conductive particles to the cross sectional area of said semiconductor region keeps constant or varies at different distances to said first main surface.

4. A semiconductor device according to claim 1, wherein said semiconductor region of said voltage-sustaining region includes a semiconductor region of a first conductivity type and/or a semiconductor region of a second conductivity type.

5. A semiconductor device according to claim 1, wherein said second device feature region is a semiconductor region of a first conductivity type;
wherein said first device feature region includes a semiconductor region of a second conductivity type contacted directly with said semiconductor region of said voltage-sustaining region;
and wherein said first device feature region further includes a semiconductor region of said second conductivity type or a conductor being contacted directly with said insulator region containing conductive particles of said voltage-sustaining region.

6. A semiconductor device according to claim 1, wherein said second device feature region has a semiconductor region of a second conductivity type being contacted directly with said second main surface and a semiconductor region of a first conductivity type being contacted directly with said semiconductor region of said second conductivity type; wherein said semiconductor region of said first conductivity type is further contacted with said voltage-sustaining region;
wherein said first device feature region includes a semiconductor region of said second conductivity type contacted directly with said semiconductor region of said first conductivity type of said voltage-sustaining region;
and wherein said first device feature region further includes a semiconductor region of said second conductivity type or a conductor being contacted directly with said insulator region containing conductive particles of said voltage-sustaining region.

7. A semiconductor device according to claim 1, said semiconductor device being a Schottky diode with a metal-semiconductor contact, wherein said second device feature region is a semiconductor region of a first conductivity type;
wherein said first device feature region is made of metal being contacted directly with a semiconductor region of said first conductivity type of said voltage-sustaining region;
wherein said first device feature region and said second device feature region are contacted with two conductors respectively serving as two electrodes of said Schottky diode;
and wherein said first device feature region further has a semiconductor region of a second conductivity type or a conductor being contacted directly with said insulator region containing conductive particles of said voltage-sustaining region.

8. A semiconductor device according to claim 1, said semiconductor device being a Junction Barrier Controlled Schottky (JBS) rectifier or a Merged P-i-N/Schottky (MPS) rectifier, wherein said second device feature region is a semiconductor region of a first conductivity type;
wherein said first device feature region includes a metal region being contacted directly with a semiconductor region of said first conductivity type of said voltage-sustaining region;
wherein said first device feature region further includes a semiconductor region of a second conductivity type being contacted directly with semiconductor region of said first conductivity type of said voltage-sustaining region and said metal region;
and wherein said first device feature region and said second device feature region are contacted with two conductors respectively serving as two electrodes of said JBS rectifier or said MPS rectifier.

9. A semiconductor device according to claim 5, said semiconductor device being a Bipolar Junction Transistor (BJT), wherein said second device feature region is a semiconductor region of said first conductivity type;
wherein said voltage-sustaining region has at least a semiconductor region of said first conductivity type serving as a collector region of said BJT;
wherein said semiconductor region of said second conductivity type of said first device feature region serves as a base region of said BJT;
wherein said first device feature region further includes a semiconductor region of said first conductivity type surrounded by said base region except the part on said first main surface, serving as an emitter region of said BJT;
and wherein a conductor covering on said semiconductor region of said first conductivity type of said second device feature region serves as a collector electrode, a conductor covering on said base region serves as a base electrode and a conductor covering on said emitter region serves as an emitter electrode.

10. A semiconductor device according to claim 5, said semiconductor device being a Metal-Insulator-Semiconductor Field Effect Transistor (MISFET), wherein said second device feature region is a semiconductor region of said first conductivity type, serving as drain region of said MISFET;
wherein said voltage-sustaining region has at least a semiconductor region of said first conductivity type serving as a drift region of said MISFET;
wherein said semiconductor region of said second conductivity type of said first device feature region serves as a source-body region of said MISFET;
wherein said first device feature region further includes a semiconductor region of said first conductivity type surrounded by said source-body region except the part on said first main surface, serving as a source region of said MISFET;
wherein an insulator layer covers on said first main surface started from a part of said source region, through an area of said source-body region, ended at a part of said semiconductor region of said first conductivity type of said voltage-sustaining region, serving as a gate insulator of said MISFET;
and wherein a conductor covering on said drain region serves as a drain electrode, a conductor contacted with both said source-body region and said source region serves as a source electrode and a conductor covering on said gate insulator serves as a gate electrode.

11. A semiconductor device according to claim 6, said semiconductor device being an Insulator Gate Bipolar Transistor (IGBT), wherein said semiconductor region of said second conductivity type of said second device feature region is an anode region of said IGBT;
wherein said semiconductor region of said second conductivity type of said first device feature region serves as a source-body region of MISFET in said IGBT;
wherein said first device feature region further includes a semiconductor region of said first conductivity type surrounded by said source-body region except the part on said first main surface, serving as a source region of said MISFET in said IGBT;
wherein an insulator layer covers on said first main surface starting from a part of said source region, through an area of said source-body region, ending at a part of said semiconductor region of said first conductivity type of said voltage-sustaining region, serving as a gate insulator of said MISFET in said IGBT;
and wherein a conductor covering on said anode region serves as an anode electrode, a conductor contacted with both said source-body region and said source region serves as a cathode electrode and a conductor covering on said gate insulator serves as a gate electrode.

12. A semiconductor device according to claim 6, said semiconductor device being a thyristor, wherein said semiconductor region of said second conductivity type in said second device feature region is an anode region of said thyristor;
wherein said semiconductor region of said second conductivity type of said first device feature region serves as a gate region of said thyristor;
wherein said first device feature region further includes a semiconductor region of said first conductivity type surrounded by said gate region except the part on said first main surface, serving as a cathode region of said thyristor;
wherein a conductor covering on a part of said gate region and said insulator region containing conductive particles of said voltage-sustaining region serves as a gate electrode of said thyristor;
and wherein a conductor covering on said anode region serves as an anode electrode and a conductor covering on said cathode region serves as a cathode electrode.

13. A semiconductor device according to claim 1, wherein a cell of said semiconductor device is located at an edge of an operation region of a semiconductor device, serving as a junction edge technique for sustaining voltage; and wherein said insulator containing conductive particles of said voltage-sustaining region is contacted with a semiconductor region of a second conductivity type of said first device feature region through a semiconductor region of said second conductivity type or a conductor.
